(19) United States
(12) Patent Application Publication
(10) Pub. No.: US 2022/0203496 A1
(43) Pub. Date: Jun. 30, 2022

(54) POLISHING PAD, MANUFACTURING METHOD THEREOF, METHOD FOR MANUFACTURING SEMICONDUCTOR DEVICE USING SAME

(71) Applicant: SKC solmics Co., Ltd., Gyeonggi-do (KR)

(72) Inventors: Jong Wook YUN, Seoul (KR); Hye Young HEO, Gyeonggi-do (KR); Eun Sun JOENG, Gyeonggi-do (KR); Jae In AHN, Gyeonggi-do (KR)

(21) Appl. No.: 17/564,742

(22) Filed: Dec. 29, 2021

(30) Foreign Application Priority Data
Dec. 30, 2020 (KR) 10-2020-0187473

(51) Int. Cl. B24B 37/24; B24B 37/22; B24B 37/26; C08J 9/236; B29C 44/34; B29C 44/36; C08G 18/08; C08G 18/48; C08G 18/10; C08G 18/32; C08G 18/18

(52) U.S. Cl. CPC B24B 37/24; B24B 37/22; B24B 37/26; C08J 9/236; B29C 44/3461; B29C 44/36; C08G 2101/00; C08G 18/4854; C08G 18/10; C08G 18/3206; C08G 18/18; C08J 2201/022; C08J 2203/22; C08G 18/14

(57) ABSTRACT

The present disclosure relates to a polishing pad, a method for manufacturing the polishing pad, and a method for manufacturing a semiconductor device using the polishing pad. The polishing pad increases the area in direct contact with the semiconductor substrate during the polishing process and can prevent defects occurring on the surface of the semiconductor substrate by forming a plurality of uniform pores in the polishing layer, thereby adjusting the surface roughness characteristics of the polishing surface of the polishing layer. Further, the present disclosure may provide a method for manufacturing a semiconductor device to which the polishing pad is applied.

### CROSS-REFERENCE TO RELATED APPLICATION(S)

This application claims priority to Korean Patent Application No. 10-2020-0187473, filed on Dec. 30, 2020, the disclosure of which is incorporated herein by reference in its entirety.

### TECHNICAL FIELD

The present disclosure relates to a polishing pad used in a chemical mechanical planarization (CMP) process, a manufacturing method thereof, and a method for manufacturing a semiconductor device using the same.

### DESCRIPTION OF THE RELATED ART

The chemical mechanical planarization (CMP) process during the semiconductor manufacturing process is a process of mechanically planarizing the concave-convex part of the wafer surface by moving the platen and the head relative to each other while chemically reacting the surface of the wafer by supplying a slurry in a state where a wafer is attached to a head and brought into contact with the surface of a polishing pad formed on a platen.

“Dishing” refers to a phenomenon in which CMP polishing causes a metal recess in a low area, such as an oxide cavity or trough, where the metal layer does not remain although a metal layer should remain parallel to or on the same plane as the underlying layer of the substrate wafer after CMP polishing.

The dishing problem has recently been recognized as an important problem as semiconductor wafers and devices become increasingly complex with microscopic features and more metallization layers. This trend calls for more improved performance for consumables used in polishing processes in order to maintain flatness and limit polishing defects.

Defects in such wafers and devices may cause electrical insulation or short circuits in conductive lines that make the semiconductor device inoperable. Polishing defects may be reduced by using a soft polishing pad in order to reduce polishing defects such as micro-scratches or chatter marks.

Further, CMP polishing of a soft metal layer may reduce polishing defects through the use of a softer CMP polishing pad.

However, although CMP polishing using a soft pad may improve defects on the polished substrate, such a soft pad may cause a problem of increasing dishing on the metallized semiconductor wafer surface due to the flexible characteristics of the soft pad.

Accordingly, there is a need for development of a polishing pad which can reduce dishing on the substrate surface that may occur due to the CMP polishing process for the metal surface in the semiconductor wafer or device substrate, can minimize polishing defects that may occur on the wafer, and can exhibit polishing performance suitable for the process.

### SUMMARY

An object of the present disclosure is to provide a polishing pad, a manufacturing method thereof, and a method for manufacturing a semiconductor device using the same.

Another object of the present disclosure is to provide a polishing pad which increases the area in direct contact with the semiconductor substrate during the polishing process and lowers the Sₚₖ reduction rate of the polishing surface so that defects occurring on the surface of the semiconductor substrate can be prevented by forming pores with a uniform size in the polishing layer in the polishing pad, thereby adjusting the surface roughness characteristics of the polishing layer to the polishing surface.

Another object of the present disclosure is to provide a method for manufacturing a polishing pad in which a plurality of pores that have a small diameter size and are uniform are formed in the polishing layer by containing an unexpanded solid-phase foaming agent and a catalyst in the polishing composition when the polishing layer is manufactured, and expanding the solid-phase foaming agent during the curing process.

Another object of the present disclosure is to provide a method for manufacturing a semiconductor device to which the polishing pad is applied.

In order to achieve the above object, a polishing pad according to an embodiment of the present disclosure comprises a polishing layer, and a polishing surface of the polishing layer has a Sₚₖ reduction rate according to the following Equation 1 of 5 to 25%:

$$\frac{\vert Initial {S}_{pk} - After polishing {S}_{pk} \vert}{Initial {S}_{pk}} \qquad [ Equation 1 ]$$

where,

Sₚₖ relates to a three-dimensional parameter for surface roughness, and means the average height of the protruding peak after expressing the height of the total surface roughness in a graph,

the initial Sₚₖ is Sₚₖ for the polishing surface before the polishing process, and

Sₚₖ after polishing is Sₚₖ for the polishing surface after attaching a 300 mm diameter silicon wafer on which silicon oxide is deposited to a surface plate, maintaining a polishing load of 4.0 psi and a rotational speed of the polishing pad of 150 rpm, injecting the calcined ceria slurry at a rate of 250 ml/min, and performing the polishing process for 60 seconds.

A method for manufacturing a polishing pad according to another embodiment of the present disclosure comprises the steps of: i) preparing a prepolymer composition; ii) preparing a composition for manufacturing a polishing layer, comprising the prepolymer composition, a foaming agent, a curing agent, and a catalyst; and iii) manufacturing a polishing layer by curing the composition for manufacturing the polishing layer, wherein a polishing surface of the polishing layer has a Sₚₖ reduction rate according to the following Equation 1 of 5 to 25%:

$$\frac{\vert Initial {S}_{pk} - After polishing {S}_{pk} \vert}{Initial {S}_{pk}} \qquad [ Equation 1 ]$$

where,

Sₚₖ relates to a three-dimensional parameter for surface roughness, and means the average height of the protruding peak after expressing the height of the total surface roughness in a graph,

the initial Sₚₖ is Sₚₖ for the polishing surface before the polishing process, and

Sₚₖ after polishing is Sₚₖ for the polishing surface after attaching a 300 mm diameter silicon wafer on which silicon oxide is deposited to a surface plate, maintaining a polishing load of 4.0 psi and a rotational speed of the polishing pad of 150 rpm, injecting the calcined ceria slurry at a rate of 250 ml/min, and performing the polishing process for 60 seconds.

A method for manufacturing a semiconductor device according to another embodiment of the present disclosure comprises the steps of: 1) providing a polishing pad comprising a polishing layer; and 2) polishing the semiconductor substrate while relatively rotating them so that the surface to be polished of a semiconductor substrate comes into contact with a polishing surface of the polishing layer, wherein the polishing surface of the polishing layer has a Sₚₖ reduction rate according to the following Equation 1 of 5 to 25%:

$$\frac{\vert Initial {S}_{pk} - After polishing {S}_{pk} \vert}{Initial {S}_{pk}} \qquad [ Equation 1 ]$$

where,

Sₚₖ relates to a three-dimensional parameter for surface roughness, and means the average height of the protruding peak after expressing the height of the total surface roughness in a graph,

the initial Sₚₖ is Sₚₖ for the polishing surface before the polishing process, and

Sₚₖ after polishing is Sₚₖ for the polishing surface after attaching a 300 mm diameter silicon wafer on which silicon oxide is deposited to a surface plate, maintaining a polishing load of 4.0 psi and a rotational speed of the polishing pad of 150 rpm, injecting the calcined ceria slurry at a rate of 250 ml/min, and performing the polishing process for 60 seconds.

The polishing pad according to the present disclosure adjusts the surface roughness characteristics of the polishing surface of the polishing layer to increase the area in direct contact with the semiconductor substrate during the polishing process and lowers the Sₚₖ reduction rate of the polishing surface to enable defects occurring on the surface of the semiconductor substrate to be prevented by comprising an unexpanded solid-phase foaming agent in the polishing composition when the polishing layer is manufactured and expanding the solid-phase foaming agent during the curing process, thereby forming a plurality of pores that have a small diameter size and are uniform in the polishing layer.

Further, the present disclosure may provide a method for manufacturing a semiconductor device to which the polishing pad is applied.

### BRIEF DESCRIPTION OF THE DRAWINGS

FIG. 1 relates to Sₚₖ which is a three-dimensional surface roughness parameter according to an embodiment of the present disclosure.

FIG. 2 is a graph for a volume cumulative diameter according to an embodiment of the present disclosure.

FIGS. 3A and 3B are diagrams showing the number of contact peaks between a polishing surface and a semiconductor substrate according to an embodiment of the present disclosure.

FIG. 4 is a conceptual diagram of a solid-phase foaming agent contained when manufacturing a polishing layer according to an embodiment of the present disclosure.

FIG. 5 is a conceptual diagram of foaming of a solid-phase foaming agent when manufacturing a polishing layer according to an embodiment of the present disclosure.

FIG. 6 is a schematic process diagram of a semiconductor device manufacturing process according to an embodiment of the present disclosure.

FIG. 7 is an SEM measurement result of the pores of the polishing layer according to an embodiment of the present disclosure.

FIG. 8 is an SEM measurement result of the pores of the polishing layer according to an embodiment of the present disclosure.

FIG. 9 is an SEM measurement result of the pores of the polishing layer according to an embodiment of the present disclosure.

FIG. 10 is an SEM measurement result of the pores of the polishing layer according to an embodiment of the present disclosure.

FIG. 11 is an SEM measurement result after performing a polishing process on a polishing surface according to an embodiment of the present disclosure.

FIG. 12 is an SEM measurement result after performing a polishing process on a polishing surface according to an embodiment of the present disclosure.

FIG. 13 is an SEM measurement result after performing a polishing process on a polishing surface according to an embodiment of the present disclosure.

FIG. 14 is an SEM measurement result after performing a polishing process on a polishing surface according to an embodiment of the present disclosure.

FIG. 15 is an SEM measurement result after performing a polishing process on a polishing surface according to an embodiment of the present disclosure.

FIG. 16 is an SEM measurement result after performing a polishing process on a polishing surface according to an embodiment of the present disclosure.

FIG. 17 is an SEM measurement result after performing a polishing process on a polishing surface according to an embodiment of the present disclosure.

FIG. 18 is an SEM measurement result after performing a polishing process on a polishing surface according to an embodiment of the present disclosure.

### DESCRIPTION OF SPECIFIC EMBODIMENTS

Hereinafter, embodiments of the present disclosure will be described in detail so that those with ordinary skill in the art to which the present disclosure pertains will be able to easily implement the present disclosure. However, the present disclosure may be embodied in various different forms and is not limited to the embodiments described herein.

It should be understood that numbers expressing quantities of components, properties such as molecular weight, reaction conditions, etc. used in the present disclosure are modified with the term “about” in all cases.

Unless otherwise stated in the present disclosure, all percentages, parts, ratios, etc. are by weight.

In the present disclosure, if a prescribed part “includes” a prescribed element, this means that another element can be further included instead of excluding other elements unless any particularly opposite description exists.

In the present disclosure, “a plurality” refers to more than one.

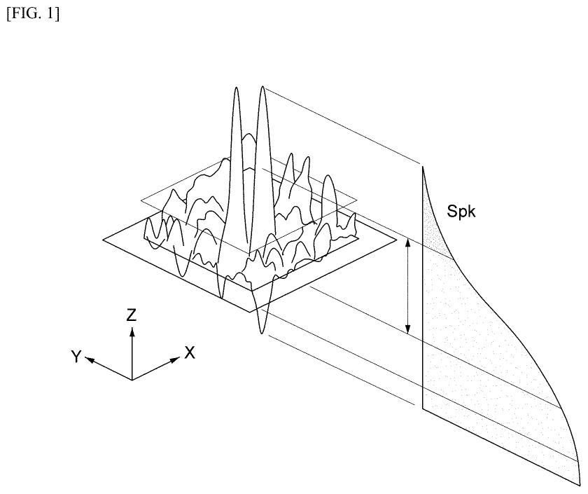

In the present disclosure, “Sₚk” relates to a three-dimensional parameter for surface roughness, and means the average height of the protruding peak after expressing the height of the total surface roughness in a graph as shown in FIG. 1.

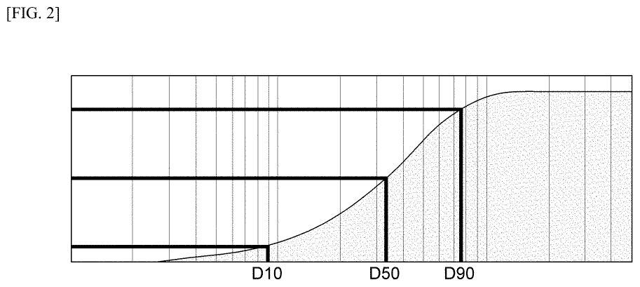

In the present disclosure, “10% cumulative diameter by volume”, “50% cumulative diameter by volume” and “90% cumulative diameter by volume” are particle diameters respectively representing 10%, 50%, and 90% of the cumulative frequency distribution of the volume particle diameter. In more detail, as shown in FIG. 2, the Y-axis means volume (%) and the X-axis means diameter (m), and the cumulative frequency distribution of the pore volume with respect to the diameter of the pores is obtained by dividing the sum of the volumes of the pores up to the corresponding diameter by the sum of the volumes of all pores as the diameter of the pores increases. That is, the 10% cumulative diameter by volume refers to the corresponding diameter when the volumes of pores having a gradually larger diameter from the pores having the smallest diameter are cumulatively added and the cumulatively added volume is 10%, i.e., the largest diameter at this time. Further, the 50% cumulative diameter by volume refers to the corresponding diameter when the volumes of pores having a gradually larger diameter from the pores having the smallest diameter are cumulatively added and the cumulatively added volume is 50%, i.e., the largest diameter at this time. Further, the 90% cumulative diameter by volume refers to the corresponding diameter when the volumes of pores having a gradually larger diameter from the pores having the smallest diameter are cumulatively added and the cumulatively added volume is 90%, i.e., the largest diameter at this time.

A polishing pad according to an embodiment of the present disclosure may include a polishing layer, and the polishing surface of the polishing layer may have a Sₚₖ reduction rate according to the following Equation 1 of 5 to 25%, 5 to 20%, 6 to 15%, or 6 to 12%:

$$\frac{\vert Initial {S}_{pk} - After polishing {S}_{pk} \vert}{Initial {S}_{pk}} \qquad [ Equation 1 ]$$

where,

Sₚₖ relates to a three-dimensional parameter for surface roughness, and means the average height of the protruding peak after expressing the height of the total surface roughness in a graph,

the initial Sₚₖ is Sₚₖ for the polishing surface of the polishing layer before the polishing process, and

Sₚₖ after polishing is Sₚₖ for the polishing surface of the polishing layer measured after attaching the polishing pad to a surface plate with respect to a 300 mm diameter silicon wafer on which silicon oxide is deposited, maintaining a polishing load of 4.0 psi and a rotational speed of the polishing pad of 150 rpm, injecting the calcined ceria slurry at a rate of 250 ml/min, and performing the polishing process for 60 seconds.

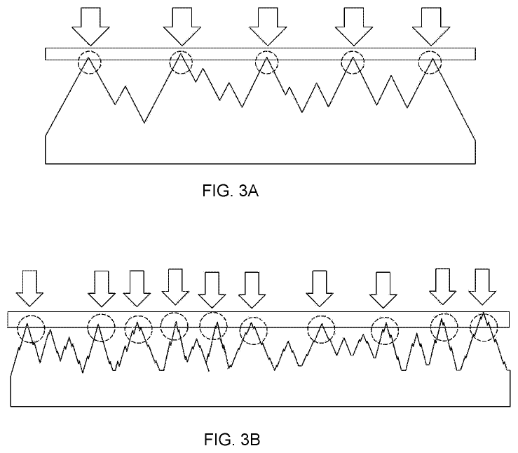

The Sₚₖ reduction rate refers to the ability to maintain the irregularities without irregularities formed on the polishing surface of the polishing layer being collapsed by the polishing process. Specifically, as shown in FIGS. 3A and 3B, a particularly protruding portion among the irregularities formed on the polishing surface refers to a portion in direct contact with the semiconductor substrate in the polishing process, and FIG. 3A is a view meaning a polishing surface having a relatively small number of peaks formed thereon, and FIG. 3B is a view meaning a large number of peaks in direct contact with the semiconductor substrate as in the present disclosure.

FIGS. 3A and 3B show the same numerical values when measuring the average heights of the protruding peaks from the central roughness cross-sectional curves, but Sₚₖ is obtained by measuring the average area of the protruding peaks so that it can be confirmed that there is a difference therebetween.

FIGS. 3A and 3B show differences in the number of direct contacts of peaks of a polishing surface with a semiconductor substrate in the polishing process, and a difference in the Sₚₖ reduction rate before and after the polishing process due to such a difference.

That is, since the number of contacts is small in FIG. 3A compared to FIG. 3B, the irregularities of the polishing surface are reduced by the polishing process so that the Sₚₖ reduction rate is shown to be large, whereas the Sₚₖ reduction rate is shown to be small since the number of contacts is large in FIG. 3B although the irregularities of the polishing surface are partially reduced by the polishing process.

The difference in the Sₚₖ reduction rate may exhibit a stress relaxation effect between the polishing surface and the semiconductor substrate in the polishing process, and the occurrence of defects in the semiconductor substrate after the polishing process may be prevented due to the above-described effect.

As described above, allowing the Sₚₖ reduction rate of the polishing layer of the present disclosure to be exhibited to be small is due to controlling the size of the micropores contained in the polishing layer. That is, the polishing layer is characterized in that a plurality of pores are formed therein, and the Sₚₖ reduction rate may be decreased and the occurrence of defects in the polishing process may be prevented by controlling the diameter of the pores to be small, thereby controlling the surface roughness of the polishing surface.

When manufacturing a polishing layer in the conventional polishing pad, pores having irregular sizes and arrangements are formed by a physical method or a chemical method. According to a conventional method for manufacturing a polishing layer, pores of various shapes and sizes are arranged in irregularly dispersed forms on the surface and inside of the polishing layer made of a polymer material.

A physical method among conventional methods of forming pores or holes in the polishing layer is to mix a micro-sized material with a forming material of the polishing layer. In this case, micro-sized materials with cavities should be put in to mix well with the polymer at the beginning of the polishing layer manufacturing.

However, in the physical method, it is difficult to initially mix the micro-sized materials uniformly and well with the polymer, and the size of the micro-sized materials is also not constant.

In general, the pores formed by the physical method have an average diameter of about 100 micrometers, and the diameter of each pore ranges from several tens of micrometers to several hundreds of micrometers. This is a phenomenon that occurs because of the limitations of the technology for making the pores. Further, when the polishing pad is manufactured, the distribution also varies depending on the location due to gravity so that it is not easy to manufacture a polishing layer having uniform performance.

Since the size or distribution of the formed pores is not constant in the polishing layer manufactured as in the above-described physical method, there is a problem in that when the semiconductor substrate is polished to ultra-precision, the efficiency varies depending on the area in contact with the polishing layer or time.

Alternatively, by a chemical method, pores may be formed in the CMP polishing pad, and when water, or a liquid that can easily change to a gaseous state is put together in a polymer solution and heated to a low temperature, a phenomenon that the pores are formed while the liquid turns into a gas may be used.

However, a method of forming pores inside by using a gas in this way also has a problem in that it is difficult to constantly maintain the size of the pores.

A polishing pad is a consumable item used to polish the surface of a semiconductor substrate, and is an indispensable and important part. The slurry exists between the polishing pad and the surface of the semiconductor substrate while performing the polishing process and chemically and mechanically polishes the surface of the semiconductor substrate, and the used slurry is discharged to the outside.

In order for the slurry to be present on the polishing pad for a predetermined time, the polishing pad should be able to store the slurry. Such a slurry storage function of the polishing pad may be performed by pores or grooves formed in the polishing pad.

That is, the slurry penetrates into the pores or grooves formed in the polishing pad to efficiently polish the surface of the semiconductor substrate for a long time. In order for the polishing pad to suppress the outflow of the slurry as much as possible and obtain good polishing efficiency, the shape of pores or grooves should be well controlled, and physical properties such as hardness of the polishing pad should maintain optimal conditions.

Accordingly, the polishing pad of the present disclosure may prevent defects occurring in the polishing process by controlling a plurality of pores formed in the polishing layer to a predetermined size. Specifically, the polishing layer of the present disclosure may include a plurality of pores, and the pores may have a D10 of 10 to 20 μm, 11 to 18 μm, 12 to 17 μm, or 13 to 16 μm. The pores may have a D50 of 15 to 30 μm, 16 to 28 μm, 17 to 26 μm, 18 to 24 μm, or 18 to 22 μm. The pores may have a D90 of 20 to 45 μm, 21 to 35 μm, 22 to 30 μm, or 23 to 28 μm. The present disclosure is characterized in that the size and distribution of pore diameters are very small and narrowly distributed.

That is, when manufacturing a polishing layer, the polishing layer is manufactured by molding a cured product obtained by curing a composition comprising a polyurethane-based prepolymer, a curing agent, a foaming agent, and a catalyst, and the manufactured polishing layer is characterized by having a plurality of pores formed therein.

As described above, a physical method or a chemical method is used to form the pores in the polishing layer, and a chemical method has recently been used when manufacturing the polishing layer.

That is, the pores are formed by injecting a liquid-phase foaming agent or gas as a foaming agent, but in the case of the above method, since the liquid-phase foaming agent is vaporized in the curing process to form pores, it is not easy to control the size of the pores formed, and even when the gas is injected, it is not easy to control the size when forming the pores.

Accordingly, the present disclosure is characterized in that an unexpanded solid-phase foaming agent is used.

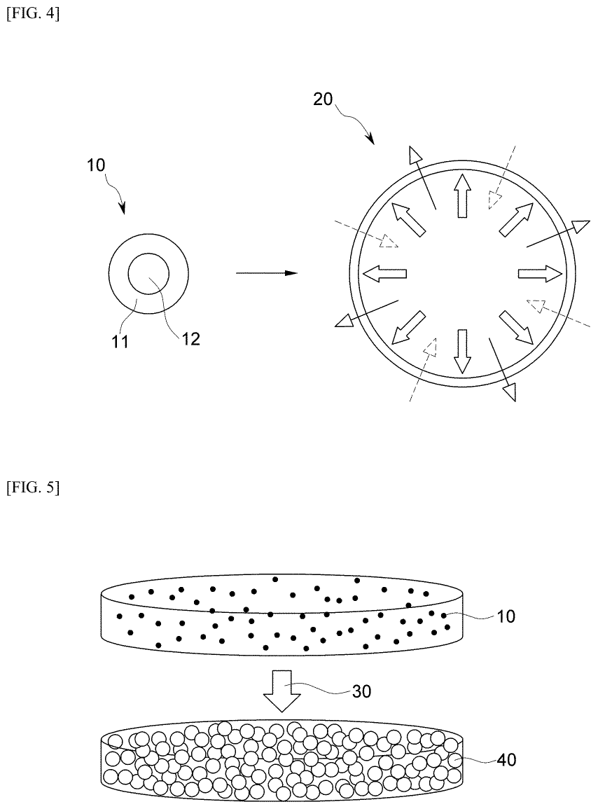

The foaming agent is unexpanded particles 10 as shown in FIG. 4, and the unexpanded particles 10 may comprise a resin material shell 11 and an expansion-causing component 12 encapsulated by the shell.

The unexpanded particles 10 are particles which have not been pre-expanded, and refer to particles whose final sizes are determined by being expanded by heat or pressure applied in the manufacturing process of the polishing layer.

The unexpanded particles 10 may form a plurality of pores in the polishing layer by being foamed by a curing process.

In order to manufacture a conventional polishing layer, expanded particles used are not separately expanded in the curing process. However, the foaming agent of the present disclosure may include unexpanded particles as a foaming agent 10, and a plurality of pores are formed by expanding 20 the unexpanded particles 10 in the curing process.

The unexpanded particles 10 may comprise a resin material shell 11; and an expansion-causing component 12 that is present in the inside encapsulated by the shell.

For example, the shell 11 may contain a thermoplastic resin, and the thermoplastic resin may be one or more selected from the group consisting of a vinylidene chloride-based copolymer, an acrylonitrile-based copolymer, a methacrylonitrile-based copolymer, and an acrylic copolymer.

The expansion-causing component 12 may include one selected from the group consisting of a hydrocarbon compound, a chlorofluoro compound, a tetraalkylsilane compound, and combinations thereof.

Specifically, the hydrocarbon compound may include one selected from the group consisting of ethane, ethylene, propane, propene, n-butane, isobutane, n-butene, isobutene, n-pentane, isopentane, neopentane, n-hexane, heptane, petroleum ether, and combinations thereof.

The chlorofluoro compound may include one selected from the group consisting of trichlorofluoromethane (CCl₃F), dichlorodifluoromethane (CCl₂F₂), chlorotrifluoromethane (CClF₃), tetrafluoroethylene (CClF₂—CClF₂), and combinations thereof.

The tetraalkylsilane compound may include one selected from the group consisting of tetramethylsilane, trimethylethylsilane, trimethylisopropylsilane, trimethyl-n-propylsilane, and combinations thereof.

Specifically, the unexpanded particles 10 comprise a thermoplastic resin shell 11 of and a hydrocarbon gas 12 inside the shell. The internal hydrocarbon gas may serve to expand the thermoplastic resin shell by heat applied in the curing process.

When the size of the polymer shell is expanded by the expansion as described above, and the internal hydrocarbon gas is flown out to the outside, pores may be formed in the polishing layer, and the polymer shell may be included in the polishing layer.

The solid-phase foaming agent may be contained in an amount of 0.5 to 10 parts by weight, for example, 1 to 7 parts by weight, for example, 1 to 5 parts by weight based on 100 parts by weight of the urethane-based prepolymer composition. The type and content of the solid-phase foaming agent may be designed depending on the desired pore structure and physical properties of the polishing layer.

The composition for manufacturing the polishing layer of the present disclosure may comprise one selected from the group consisting of an expanded solid-phase foaming agent, a gas-phase foaming agent, a liquid-phase foaming agent, and combinations thereof, as well as the unexpanded solid-phase foaming agent described above.

The gas-phase foaming agent may comprise an inert gas. The gas-phase foaming agent may be used as a pore-forming element by being injected in a process in which the urethane-based prepolymer and the curing agent are reacted.

The type thereof is not particularly limited as long as the inert gas is a gas that does not participate in the reaction between the urethane-based prepolymer and the curing agent. For example, the inert gas may include one selected from the group consisting of nitrogen gas (N₂), argon gas (Ar), helium gas (He), and combinations thereof.

Specifically, the inert gas may include nitrogen gas (N₂) or argon gas (Ar).

The type and content of the gas-phase foaming agent may be designed depending on the desired pore structure and physical properties of the polishing layer.

The particles of the thermally expanded solid-phase foaming agent may be particles having an average particle diameter of about 5 to 200 μm. The thermally expanded particles may have an average particle diameter of about 5 to 100 μm, for example, about 10 to 80 μm, for example, about 20 to 70 μm, for example, about 20 to 50 μm, for example, about 30 to 70 μm, for example, about 25 to 45 μm, for example, about 40 to 70 μm, for example, about 40 to 60 μm. The average particle diameter is defined as D50 of the thermally expanded particles.

In an embodiment, the thermally expanded particles may have a density of about 30 to 80 kg/m³, for example, about 35 to 80 kg/m³, for example, about 35 to 75 kg/m³, for example, about 38 to 72 kg/m³, for example, about 40 to 75 kg/m³, for example, about 40 to 72 kg/m³.

In an embodiment, the foaming agent may include a gas-phase foaming agent. For example, the foaming agent may include a solid-phase foaming agent and a gas-phase foaming agent. Matters regarding the solid-phase foaming agent are the same as described above.

The gas-phase foaming agent may comprise nitrogen gas.

The gas-phase foaming agent may be injected through a predetermined injection line during the process of mixing the urethane-based prepolymer, the solid-phase foaming agent, and the curing agent. The gas-phase foaming agent may have an injection rate of about 0.8 to 2.0 L/min, for example, about 0.8 to 1.8 L/min, for example, about 0.8 to 1.7 L/min, for example, about 1.0 to 2.0 L/min, for example, about 1.0 to 1.8 L/min, for example, about 1.0 to 1.7 L/min.

Further, it may be said to be possible to control the size of the pores and adjust the surface properties of the polishing surface by controlling the expansibility of the foaming agent in the composition for manufacturing a polishing layer through the use of a catalyst as well as the use of an unexpanded solid-phase foaming agent in order to control the size of the pores.

The catalyst may be selected from the group consisting of an amine-based catalyst, a bismuth-based metal catalyst, an Sn-based metal catalyst, and mixtures thereof.

The amine-based catalyst is a tertiary amine-based catalyst, and specifically, a triethyl amine catalyst may be used, but all catalysts capable of exhibiting the properties of the present disclosure without being limited to the above examples may be used without limitation.

Specifically, a metal catalyst selected from the group consisting of bismuth octoate, bismuth oxide, bismuth oxychloride, bismuth chloride, bismuth subnitrate, bismuth acetate, and mixtures thereof may be used as the bismuth-based metal catalyst, but all known bismuth-based metal catalysts that accelerate the polyurethane reaction can be used without limitation.

Specifically, a metal catalyst selected from the group consisting of SnCl₄, butyltin trichloride, dibutyltin oxide, dibutyltin dilaurate, dibutyltin bis(2-ethylhexanoate), and mixtures thereof may be used as the Sn-based metal catalyst, but all known bismuth-based metal catalysts that accelerate the polyurethane reaction can be used without limitation.

The catalyst may be contained in an amount of 0.001 to 0.01 parts by weight with respect to 100 parts by weight of the urethane-based prepolymer composition, and it may enable the expandability of the solid-phase foaming agent to be controlled through the adjustment of the curing time in the curing process when manufacturing a polishing pad to be described later.

That is, the composition for manufacturing a polishing layer is cured by the curing process, and after the composition is manufactured into the polishing layer by adjusting the curing time and catalyst content during curing, thereby controlling the expandability of the solid-phase foaming agent, it may be possible to provide the polishing layer as a polishing pad which prevents the occurrence of defects in the polishing process by forming a plurality of pores to be included in the polishing layer so that the diameter of the pores is small and the size distribution thereof is narrow, thereby adjusting the surface properties of the polishing surface.

In an embodiment, the polishing layer may include a polishing layer containing a cured product formed from a composition comprising a urethane-based prepolymer, a curing agent, a foaming agent, and a catalyst. The foaming agent and the catalyst are the same as described above, and will be excluded from the description below.

Each component contained in the composition will be described in detail below.

“Prepolymer” refers to a polymer having a relatively low molecular weight in which the polymerization degree is stopped at an intermediate stage to facilitate molding in the manufacture of a cured product. The prepolymer may be molded into a final cured product either on its own or after reacting with other polymerizable compounds.

In an embodiment, the urethane-based prepolymer may be prepared by reacting an isocyanate compound with a polyol.

The isocyanate compound used in the preparation of the urethane-based prepolymer may include one selected from the group consisting of aromatic diisocyanate, aliphatic diisocyanate, alicyclic diisocyanate, and combinations thereof.

The isocyanate compound, for example, may include one selected from the group consisting of 2,4-toluene diisocyanate (2,4-TDI), 2,6-toluene diisocyanate (2,6-TDI), naphthalene-1,5-diisocyanate, p-phenylene diisocyanate, tolidine diisocyanate, 4,4′-diphenylmethane diisocyanate, hexamethylene diisocyanate, dicyclohexylmethane diisocyanate, isophorone diisocyanate, and combinations thereof

“Polyol” refers to a compound containing at least two hydroxyl groups (—OH) per molecule. The polyol may include, for example, one selected from the group consisting of polyether polyols, polyester polyols, polycarbonate polyols, acrylic polyols, and combinations thereof.

The polyol may include, for example, one selected from the group consisting of polytetramethylene ether glycol, polypropylene ether glycol, ethylene glycol, 1,2-propylene glycol, 1,3-propylene glycol, 1,2-butanediol, 1,3-butanediol, 2-methyl-1,3-propanediol, 1,4-butanediol, neopentyl glycol, 1,5-pentanediol, 3-methyl-1,5-pentanediol, 1,6-hexanediol, diethylene glycol, dipropylene glycol, tripropylene glycol, and combinations thereof.

The polyol may have a weight average molecular weight (M_{w}) of about 100 to 3,000 g/mol. The polyol may have a weight average molecular weight (M_{w}) of, for example, about 100 to 3,000 g/mol, for example, about 100 to 2,000 g/mol, for example, about 100 to 1,800 g/mol.

In an embodiment, the polyol may include a low molecular weight polyol having a weight average molecular weight (M_{w}) of about 100 g/mol or more and less than about 300 g/mol and a high molecular weight polyol having a weight average molecular weight (M_{w}) of about 300 g/mol or more and about 1800 g/mol or less.

The urethane-based prepolymer may have a weight average molecular weight (M_{w}) of about 500 to 3,000 g/mol. The urethane-based prepolymer may have a weight average molecular weight (M_{w}) of, for example, about 600 to 2,000 g/mol, for example, about 800 to 1,000 g/mol.

In an embodiment, the isocyanate compound for preparing the urethane-based prepolymer may include an aromatic diisocyanate compound, and the aromatic diisocyanate compound may include, for example, 2,4-toluene diisocyanate (2,4-TDI) and 2,6-toluene diisocyanate (2,6-TDI). The polyol compound for preparing the urethane-based prepolymer may include polytetramethylene ether glycol (PTMEG) and diethylene glycol (DEG).

In another embodiment, the isocyanate compound for preparing the urethane-based prepolymer may include an aromatic diisocyanate compound and an alicyclic diisocyanate compound, and for example, the aromatic diisocyanate compound may include 2,4-toluene diisocyanate (2,4-TDI) and 2,6-toluene diisocyanate (2,6-TDI), and the alicyclic diisocyanate compound may include dicyclohexylmethane diisocyanate (H12MDI). The polyol compound for preparing the urethane-based prepolymer may include polytetramethylene ether glycol (PTMEG) and diethylene glycol (DEG).

The urethane-based prepolymer may have an isocyanate end group content (NCO%) of about 5 to 11% by weight, for example, about 5 to 10% by weight, for example, about 5 to 8% by weight, for example, about 8 to 10% by weight. When the urethane-based prepolymer has the NCO% in the above range, appropriate physical properties of the polishing layer in the polishing pad are exhibited so that the polishing performance required for the polishing process such as the polishing rate and the polishing profile is maintained, and defects that may be generated on the wafer in the polishing process may be minimized.

Further, dishing, recess, and erosion phenomena may be prevented, and the surface planarization in the wafer may be achieved by adjusting the polishing selectivity (Ox RR/Nt RR) of the oxide film and the nitride film.

The isocyanate end group content (NCO%) of the urethane-based prepolymer may be designed by comprehensively adjusting the type and content of the isocyanate compound and polyol compound for preparing the urethane-based prepolymer, the process conditions such as temperature, pressure, time, etc. of the process of preparing the urethane-based prepolymer, and the type and content of additives used in the preparation of the urethane-based prepolymer.

The curing agent is a compound for chemically reacting with the urethane-based prepolymer to form a final cured structure in the polishing layer, and may include, for example, an amine compound or an alcohol compound. Specifically, the curing agent may include one selected from the group consisting of aromatic amines, aliphatic amines, aromatic alcohols, aliphatic alcohols, and combinations thereof.

For example, the curing agent may include one selected from the group consisting of 4,4′-methylenebis(2-chloroaniline) (MOCA), diethyltoluenediamine (DETDA), diaminodiphenylmethane, dimethyl thio-toluene diamine (DMTDA), propanediol bis p-aminobenzoate, methylene bis(methyl anthranilate), diaminodiphenylsulfone, m-xylylenediamine, isophoronediamine, ethylenediamine, diethylenetriamine, triethylenetetramine, polypropylenediamine, polypropylenetriamine, bis(4-amino-3-chlorophenyl)methane, and combinations thereof.

The curing agent may have a content of about 18 to 27 parts by weight, for example, about 19 to 26 parts by weight, for example, about 20 to 26 parts by weight based on 100 parts by weight of the urethane-based prepolymer. When the content of the curing agent satisfies the above range, it may be more advantageous to realize the desired performance of the polishing pad.

The composition for manufacturing the polishing layer may further comprise other additives such as a surfactant, a reaction rate regulator, etc. The names such as ‘surfactant’, ‘reaction rate regulator’, etc. are names arbitrarily referred to based on the main role of the corresponding substances, and each of the corresponding substances does not necessarily perform only a function limited to the role by the corresponding name.

The surfactant is not particularly limited as long as it is a material which serves to prevent a phenomenon such as agglomeration, overlapping, or the like of pores. For example, the surfactant may include a silicone-based surfactant.

The surfactant may be used in an amount of about 0.2 to 2 parts by weight based on 100 parts by weight of the urethane-based prepolymer. Specifically, the surfactant may be contained in an amount of about 0.2 to 1.9 parts by weight, for example, about 0.2 to 1.8 parts by weight, for example, about 0.2 to 1.7 parts by weight, for example, about 0.2 to 1.6 parts by weight, for example, about 0.2 to 1.5 parts by weight, for example, about 0.5 to 1.5 parts by weight based on 100 parts by weight of the urethane-based prepolymer. When the surfactant is contained in an amount within the above range, pores derived from the gas-phase foaming agent may be stably formed and maintained in the mold.

The reaction rate regulator serves to accelerate or delay the reaction, and a reaction accelerator, a reaction retarder, or both thereof may be used depending on the purpose. The reaction rate regulator may include a reaction accelerator. For example, the reaction accelerator may be one or more reaction accelerators selected from the group consisting of a tertiary amine-based compound and an organometallic compound.

Specifically, the reaction rate regulator may include one or more selected from the group consisting of triethylenediamine, dimethylethanolamine, tetramethylbutanediamine, 2-methyl-triethylenediamine, dimethylcyclohexylamine, triethylamine, triisopropanolamine, 1,4-diazabicyclo(2,2,2)octane, bis(2-methylaminoethyl)ether, trimethylaminoethylethanolamine, N,N,N′,N″,N″-pentamethyldiethylenetriamine, dimethylaminoethylamine, dimethylaminopropylamine, benzyldimethylamine, N-ethylmorpholine, N,N-dimethylaminoethylmorpholine, N,N-dimethylcyclohexylamine, 2-methyl-2-azanovonein, dibutyltin dilaurate, stannous octoate, dibutyltin diacetate, dioctyltin diacetate, dibutyltin maleate, dibutyltin di(2-ethylhexanoate), and dibutyltin dimercaptide. Specifically, the reaction rate regulator may include one or more selected from the group consisting of benzyldimethylamine, N,N-dimethylcyclohexylamine, and triethylamine.

The reaction rate regulator may be used in an amount of about 0.05 to 2 parts by weight based on 100 parts by weight of the urethane-based prepolymer. Specifically, the reaction rate regulator may be used in an amount of about 0.05 to 1.8 parts by weight, for example, about 0.05 to 1.7 parts by weight, for example, about 0.05 to 1.6 parts by weight, for example, about 0.1 to 1.5 parts by weight, for example, about 0.1 to 0.3 parts by weight, for example, about 0.2 to 1.8 parts by weight, for example, about 0.2 to 1.7 parts by weight, for example, about 0.2 to 1.6 parts by weight, for example, about 0.2 to 1.5 parts by weight, for example, about 0.5 to 1 parts by weight based on 100 parts by weight of the urethane-based prepolymer. When the reaction rate regulator is used in the above-described amount range, the curing reaction rate of the prepolymer composition may be appropriately adjusted to enable a polishing layer having desired sized pores and hardness to be formed.

When the polishing pad includes a cushion layer, the cushion layer serves to absorb and disperse an external impact applied to the polishing layer while supporting the polishing layer, thereby enabling the damage to the polishing object or the occurrence of defects during the polishing process to which the polishing pad is applied to be minimized.

The cushion layer may include nonwoven fabric or suede, but the present disclosure is not limited thereto.

In an embodiment, the cushion layer may be a resin-impregnated nonwoven fabric. The nonwoven fabric may be a fiber nonwoven fabric including one selected from the group consisting of polyester fibers, polyamide fibers, polypropylene fibers, polyethylene fibers, and combinations thereof.

The resin impregnated into the nonwoven fabric may include one selected from the group consisting of a polyurethane resin, a polybutadiene resin, a styrene-butadiene copolymer resin, a styrene-butadiene-styrene copolymer resin, an acrylonitrile-butadiene copolymer resin, a styrene-ethylene-butadiene-styrene copolymer resin, a silicone rubber resin, a polyester-based elastomer resin, a polyamide-based elastomer resin, and combinations thereof.

Hereinafter, a method for manufacturing the polishing pad will be described in detail.

In another embodiment according to the present disclosure, there may be provided a method for manufacturing a polishing pad, the method comprising the steps of: preparing a prepolymer composition; preparing a composition for manufacturing a polishing layer, comprising the prepolymer composition, a foaming agent, and a curing agent; and curing the composition for manufacturing the polishing layer to manufacture the polishing layer.

The step of preparing the prepolymer composition may be a process of preparing a urethane-based prepolymer by reacting a diisocyanate compound and a polyol compound. Matters regarding the diisocyanate compound and the polyol compound are the same as those described above with respect to the polishing pad.

The prepolymer composition may have an isocyanate group (NCO group) content of about 5 to 15% by weight, for example, about 5 to 8% by weight, for example, about 5 to 7% by weight, for example, about 8 to 15% by weight, for example, about 8 to 14% by weight, for example, about 8 to 12% by weight, for example, about 8 to 10% by weight.

The isocyanate group content of the prepolymer composition may be derived from terminal isocyanate groups of the urethane-based prepolymer, unreacted isocyanate groups which have not been reacted in the diisocyanate compound, and the like.

The prepolymer composition may have a viscosity of about 100 to 1,000 cps, for example, about 200 to 800 cps, for example, about 200 to 600 cps, for example, about 200 to 550 cps, for example, about 300 to 500 cps at about 80° C.

The prepolymer composition is filled in a prepolymer tank from a casting machine, and at this time, the catalyst described above may be filled.

The catalyst may be contained in an amount of 0.001 to 0.01 parts by weight based on 100 parts by weight of the prepolymer, and when it is mixed and used in the above range, the surface properties of the polishing layer to the polishing surface may be adjusted by suppressing the expansibility of the solid-phase foaming agent.

The foaming agent may include an unexpanded solid-phase foaming agent as described above, and may include a mixture obtained by mixing the unexpanded solid-phase foaming agent with a foaming agent selected from the group consisting of an expanded solid-phase foaming agent, a liquid-phase foaming agent, a gas-phase foaming agent, and mixtures thereof.

For example, the foaming agent may include an unexpanded solid-phase foaming agent and an expanded solid-phase foaming agent, may include an unexpanded solid-phase foaming agent, an expanded solid-phase foaming agent, and a gas-phase foaming agent, may include an unexpanded solid-phase foaming agent and a liquid-phase foaming agent, may include an unexpanded solid-phase foaming agent, a liquid-phase foaming agent, and a gas-phase foaming agent, and may include an unexpanded solid-phase foaming agent, an expanded solid-phase foaming agent, a liquid-phase foaming agent, and a gas-phase foaming agent, wherein the foaming agent includes an unexpanded solid-phase foaming agent, and the type and content of the foaming agent may be designed depending on the desired pore structure and physical properties of the polishing layer.

When the foaming agent includes a solid-phase foaming agent, the step of preparing the composition for manufacturing the polishing layer may comprise the steps of: preparing a first preliminary composition by mixing the prepolymer composition and the solid-phase foaming agent; and mixing the first preliminary composition and a curing agent to prepare a second preliminary composition.

The first preliminary composition may have a viscosity of about 1,000 to 2,000 cps, for example, about 1,000 to 1,800 cps, for example, about 1,000 to 1,600 cps, for example, about 1,000 to 1,500 cps at about 80° C.

When the foaming agent includes a gas-phase foaming agent, the step of preparing the composition for manufacturing the polishing layer may comprise the steps of: preparing a third preliminary composition comprising the prepolymer composition and the curing agent; and injecting the gas-phase foaming agent into the third preliminary composition to prepare a fourth preliminary composition.

In an embodiment, the third preliminary composition may further comprise a solid-phase foaming agent.

In an embodiment, the process of manufacturing the polishing layer may comprise the steps of: preparing a mold preheated to a first temperature; injecting the composition for manufacturing the polishing layer into the preheated mold to cure the composition for manufacturing the polishing layer; and post-curing the cured composition for manufacturing the polishing layer under a second temperature condition higher than the preheating temperature.

In an embodiment, the first temperature may be about 60 to 100° C., for example, about 65 to 95° C., for example, about 70 to 90° C.

In an embodiment, the second temperature may be about 100 to 130° C., for example, about 100 to 125° C., for example, about 100 to 120° C.

The step of curing the composition for manufacturing the polishing layer under the first temperature may be performed for about 5 to 60 minutes, for example, about 5 to 40 minutes, for example, about 5 to 30 minutes, for example, about 5 to 25 minutes. However, since the curing time is shortened due to the use of a catalyst in the composition for manufacturing the polishing layer of the present disclosure, the step of curing the composition for manufacturing the polishing layer may be preferably performed for 50 to 100 seconds, more preferably 70 to 90 seconds, but the present disclosure is not limited to the above examples.

The step of post-curing the composition for manufacturing the polishing layer, which has been cured under the first temperature, under the second temperature may be performed for about 5 to 30 hours, for example, about 5 to 25 hours, for example, about 10 to 30 hours, for example, about 10 to 25 hours, for example, about 12 to 24 hours, for example, about 15 to 24 hours.

The solid-phase foaming agent of the present disclosure is unexpanded particles, and the unexpanded particles contained in the composition for manufacturing a polishing layer may form a plurality of pores in the polishing layer by being expanded by heat and pressure provided in the curing process.

Specifically, as shown in FIG. 5, when the composition for manufacturing a polishing layer is injected into a preheated mold and the curing process 30 is performed, the unexpanded particles 10 contained in the composition for manufacturing a polishing layer are expanded to form a plurality of pores 40.

The method for manufacturing the polishing pad may comprise a step of processing at least one surface of the polishing layer. The processing step may be forming grooves.

In another embodiment, the step of processing at least one surface of the polishing layer may include at least one of: a step (1) of forming grooves on at least one surface of the polishing layer; a step (2) of line-turning at least one surface of the polishing layer; and a step (3) of roughening at least one surface of the polishing layer.

In the step (1), the grooves may include at least one of: concentric circular grooves formed to be spaced apart from the center of the polishing layer at a predetermined interval; and radial grooves continuously connected from the center of the polishing layer to an edge of the polishing layer.

In the step (2), the line turning may be performed by a method of cutting the polishing layer by a predetermined thickness using a cutting tool.

In the step (3), the roughening may be performed by a method of processing the surface of the polishing layer with a sanding roller.

The method for manufacturing the polishing pad may further comprise a step of laminating a cushion layer on the rear surface of the polishing surface of the polishing layer.

The polishing layer and the cushion layer may be laminated through the medium of a heat-sealing adhesive.

After applying the heat-sealing adhesive onto the rear surface of the polishing surface of the polishing layer, applying the heat-sealing adhesive onto the surface of the cushion layer to be in contact with the polishing layer, and stacking the polishing layer and the cushion layer so that the respective surfaces thereof onto which the heat-sealing adhesive has been applied are in contact with each other, two layers may be fused using a pressure roller.

In another embodiment, there is a provided a method for manufacturing a semiconductor device, the method comprising the steps of: providing a polishing pad comprising a polishing layer; and polishing the polishing object while rotating the polishing layer and the polishing object relative to each other so that a surface to be polished of a polishing object is in contact with the polishing surface of the polishing layer.

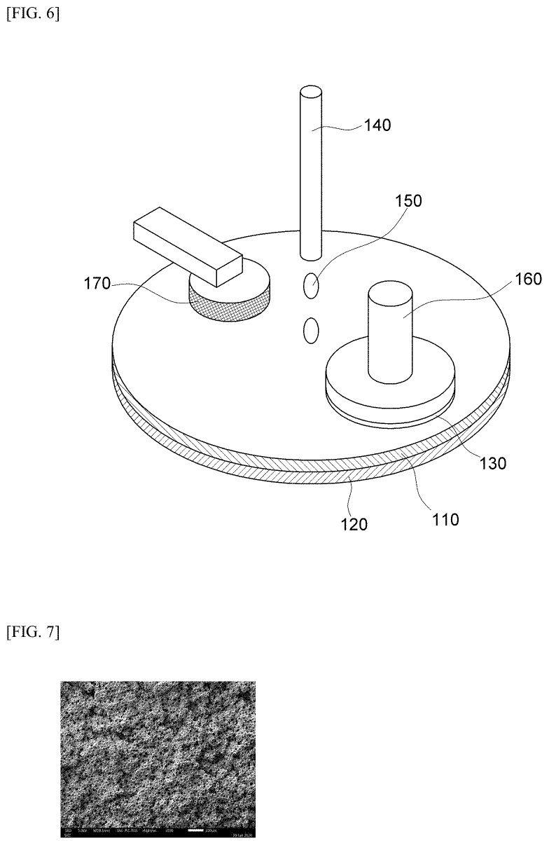

FIG. 6 is a schematic process diagram of a semiconductor device manufacturing process according to an embodiment. Referring to FIG. 6, after the polishing pad 110 according to the embodiment is mounted on the surface plate 120, the semiconductor substrate 130 that is a polishing object is disposed on the polishing pad 110.

At this time, the surface to be polished of the semiconductor substrate 130 is in direct contact with the polishing surface of the polishing pad 110. For polishing, the polishing slurry 150 may be sprayed onto the polishing pad through the nozzle 140. The flow rate of the polishing slurry 150 supplied through the nozzle 140 may be selected within the range of about 10 to 1,000 cm³/min depending on the purpose, and may be, for example, about 50 to 500 cm³/min, but the present disclosure is not limited thereto.

Thereafter, the semiconductor substrate 130 and the polishing pad 110 may be rotated relative to each other so that the surface of the semiconductor substrate 130 may be polished. At this time, the rotation direction of the semiconductor substrate 130 and the rotation direction of the polishing pad 110 may be the same direction or opposite directions.

The semiconductor substrate 130 and the polishing pad 110 may each have a rotational speed selected in a range of about 10 to 500 rpm depending on the purpose, for example, about 30 to 200 rpm, but the present disclosure is not limited thereto.

After pressing the semiconductor substrate 130 against the polishing surface of the polishing pad 110 by a predetermined load in a state that the semiconductor substrate 130 is mounted on the polishing head 160, thereby bringing the semiconductor substrate 130 into contact with the polishing surface of the polishing pad 110, the surface of the semiconductor substrate 130 may be polished. The load of the polishing surface of the polishing pad 110 applied to the surface of the semiconductor substrate 130 by the polishing head 160 may be selected in the range of about 1 to 1,000 gf/cm² depending on the purpose, and may be, for example, about 10 to 800 gf/cm², but the present disclosure is not limited thereto.

In an embodiment, in order to maintain the polishing surface of the polishing pad 110 in a state suitable for polishing, the method for manufacturing the semiconductor device may further comprise a step of processing the polishing surface of the polishing pad 110 through the conditioner 170 simultaneously along with polishing of the semiconductor substrate 130.

Hereinafter, specific Examples of the present disclosure will be presented. However, Examples described below serve merely to illustrate or explain the present disclosure in detail, and the scope of the present disclosure should not be limited thereto.

### Example 1

Manufacturing of Polishing Pad

TDI, H₁₂MDI, polytetramethylene ether glycol, and diethylene glycol were injected into a four-neck flask and reacted at 80° C. for 3 hours to prepare a prepolymer having an NCO% of 8 to 12%.

In order to manufacture a top pad, the prepared prepolymer and catalyst were filled in a prepolymer tank from a casting machine equipped with a prepolymer, a curing agent, an inert gas injection line, and a liquid-phase foaming agent injection line.

At this time, the catalyst (triethyl amine) was injected in an amount of 0.002 parts by weight based on 100 parts by weight of the prepolymer. The curing agent tank was filled with bis(4-amino-3-chlorophenyl)methane (Ishihara Corporation). The unexpanded solid-phase foaming agent (Akzonobel, 551DU40) was mixed with the prepolymer before being filled in the prepolymer tank.

During casting, the prepolymer and curing agent had an equivalent ratio adjusted to 1:1, and were discharged at a rate of 10 kg/min. After injecting inert gas nitrogen (N₂), mixing the respective injection raw materials with a mixing head, and injecting the mixture into a mold with a width of 1,000 mm, a length of 1,000 mm, and a height of 3 mm that had been preheated to 100° C., the injected mixture was cured for 80 seconds.

After the curing process, a top pad sheet which had a density of 0.7 to 0.9, and in which a plurality of pores were formed was manufactured. The manufactured top pad was subjected to surface milling processing.

### Example 2

TDI, H₁₂MDI, polytetramethylene ether glycol, and diethylene glycol were injected into a four-neck flask and reacted at 80° C. for 3 hours to prepare a prepolymer having an NCO% of 8 to 12%.

In order to manufacture a top pad, the prepared prepolymer and catalyst were filled in a prepolymer tank from a casting machine equipped with a prepolymer, a curing agent, an inert gas injection line, and a liquid-phase foaming agent injection line.

At this time, the catalyst (triethyl amine) was injected in an amount of 0.001 parts by weight based on 100 parts by weight of the prepolymer. The curing agent tank was filled with bis(4-amino-3-chlorophenyl)methane (Ishihara Corporation). The unexpanded solid-phase foaming agent (Akzonobel, 551DU40) was mixed with the prepolymer before being filled in the prepolymer tank.

During casting, the prepolymer and curing agent had an equivalent ratio adjusted to 1:1, and were discharged at a rate of 10 kg/min. After injecting inert gas nitrogen (N₂), mixing the respective injection raw materials with a mixing head, and injecting the mixture into a mold with a width of 1,000 mm, a length of 1,000 mm, and a height of 3 mm that had been preheated to 100° C., the injected mixture was cured for 88 seconds. v After the curing process, a top pad sheet which had a density of 0.7 to 0.9, and in which a plurality of pores were formed was manufactured. The manufactured top pad was subjected to surface milling processing.

### Comparative Example 1

TDI, H₁₂MDI, polytetramethylene ether glycol, and diethylene glycol were injected into a four-neck flask and reacted at 80° C. for 3 hours to prepare a prepolymer having an NCO% of 8 to 12%.

In order to manufacture a top pad, the prepared prepolymer was filled in a prepolymer tank from a casting machine equipped with a prepolymer, a curing agent, an inert gas injection line, and a liquid-phase foaming agent injection line.

The curing agent tank was filled with bis(4-amino-3-chlorophenyl)methane (Ishihara Corporation). The unexpanded solid-phase foaming agent (Akzonobel, 551DU40) was mixed with the prepolymer before being filled in the prepolymer tank.

During casting, the prepolymer and curing agent had an equivalent ratio adjusted to 1:1, and were discharged at a rate of 10 kg/min. After injecting inert gas nitrogen (N2), mixing the respective injection raw materials with a mixing head, and injecting the mixture into a mold with a width of 1,000 mm, a length of 1,000 mm, and a height of 3 mm that had been preheated to 100° C. the injected mixture was cured for 80 seconds.

After the curing process, a top pad sheet which had a density of 0.7 to 0.9, and in which a plurality of pores were formed was manufactured. The manufactured top pad was subjected to surface milling processing.

### Comparative Example 2

TDI, H₁₂MDI, polytetramethylene ether glycol, and diethylene glycol were injected into a four-neck flask and reacted at 80° C. for 3 hours to prepare a prepolymer having an NCO% of 8 to 12%.

In order to manufacture a top pad, the prepared prepolymer was filled in a prepolymer tank from a casting machine equipped with a prepolymer, a curing agent, an inert gas injection line, and a liquid-phase foaming agent injection line.

The curing agent tank was filled with bis(4-amino-3-chlorophenyl)methane (Ishihara Corporation). The expanded solid-phase foaming agent (Akzonobel, 461DET40d25) was mixed with the prepolymer before being filled in the prepolymer tank.

During casting, the prepolymer and curing agent had an equivalent ratio adjusted to 1:1, and were discharged at a rate of 10 kg/min. After injecting inert gas nitrogen (N₂), mixing the respective injection raw materials with a mixing head, and injecting the mixture into a mold with a width of 1,000 mm, a length of 1,000 mm, and a height of 3 mm that had been preheated to 100° C., the injected mixture was cured for 103 seconds.

After the curing process, a top pad sheet which had a density of 0.7 to 0.9, and in which a plurality of pores were formed was manufactured. The manufactured top pad was subjected to surface milling processing.

### Comparative Example 3

The top pad was manufactured in the same manner except that the amount of the catalyst used was different from Example 1 as shown in Table 1.

The manufacturing contents and process conditions for Examples and Comparative Examples are specifically as shown in Table 1 below.

TABLE 1

| | | | | Comparative | Comparative | Comparative |
|---|---|---|---|---|---|---|
| Classification | | Example 1 | Example 2 | Example 1 | Example 2 | Example 3 |
| Top Pad | NCO content (%) of | 8% | 8% | 8% | 8% | 8% |
| | prepolymer | | | | | |
| | Casting mold Type | Single sheet | Single sheet | Single sheet | Single sheet | Single sheet |
| | Amount of catalyst | 0.002 parts | 0.001 parts | X | 0.002 parts | 0.05 parts |
| | used | by weight | by weight | | by weight | by weight |
| | Solid-phase foaming | 551DU40 | 551DU40 | 551DU40 | 461DET40d25 | 551DU40 |
| | agent used | (Unexpanded) | (Unexpanded) | (Unexpanded) | (Expanded) | (Unexpanded) |
| | Sheet processing | Sequential | Sequential | Sequential | Sequential | Sequential |
| | (casting, cutting, | | | | | |
| | grooving) | | | | | |
| | Parts by weight of | 100 | 100 | 100 | 100 | 100 |
| | prepolymer | | | | | |
| | Parts by weight of | 1 to 5 | 1 to 5 | 1 to 5 | 1 to 5 | 1 to 5 |
| | solid-phase | | | | | |
| | foaming agent | | | | | |
| Casting | Gel Time (sec) | 80 | 88 | 80 | 80 | 28 |
| | | | | | | (Casting is |
| | | | | | | impossible) |

### Experimental Example 1

Evaluation of Physical Properties of Polishing Layers

(1) Hardness

The Shore D hardness values of the polishing pads manufactured according to Examples and Comparative Examples above were measured, and the polishing pads were cut to a size of 2 cm×2 cm (thickness: 2 mm) and left in an environment with a temperature of 25° C. and a humidity of 50±5% for 16 hours. Thereafter, the hardness values of the polishing pads were measured using a durometer (D-type durometer).

(2) Elastic Modulus

For each of the polishing pads manufactured according to Examples and Comparative Examples above, after obtaining the highest strength value just before breaking while performing a test at a speed of 500 mm/min using a universal testing machine (UTM), the slope in the region of 20 to 70% of the strain-stress curve was calculated through the obtained value.

(3) Elongation

For each of the polishing pads manufactured according to Examples and Comparative Examples above, after measuring the maximum amount of deformation just before breaking while performing a test at a speed of 500 mm/min using a universal testing machine (UTM), the ratio of the maximum amount of deformation to the initial length was expressed as a percentage (%).

(4) Tensile Strength

For each of the polishing pads manufactured according to Examples and

Comparative Examples above, after obtaining the highest strength value just before breaking while performing a test at a speed of 500 mm/min using a universal testing machine (UTM), the slope in the region of 20 to 70% of the strain-stress curve was calculated through the obtained value.

(5) Specific Gravity

The specific gravity values of the polishing pads manufactured according to Examples and Comparative Examples above were measured, and the polishing pads were cut to a size of 2 cm×2 cm (thickness: 2 mm) and left in an environment with a temperature of 25° C. and a humidity of 50±5% for 16 hours. Thereafter, the density values were obtained after measuring the initial weights and the weights when the polishing pads were immersed in water using an electronic densimeter.

TABLE 2

| | | | | | Comparative | Comparative | Comparative |
|---|---|---|---|---|---|---|---|
| Classification | | Evaluation items | Example 1 | Example 2 | Example 1 | Example 2 | Example 3 |
| Physical | Top | Thickness (mm) | 2 | 2 | 2 | 2 | Casting is |
| properties | pad | Hardness (Shore D) | 57.8 | 58.2 | 57.5 | 58.5 | impossible, |
| | | Specific gravity (g/cc) | 0.78 | 0.78 | 0.78 | 0.78 | and physical |
| | | Tensile strength (N/mm2) | 22.3 | 22.2 | 21.8 | 21.9 | property |
| | | Elongation (%) | 88.1 | 87.2 | 85.6 | 86.6 | measurement |
| | | Elastic modulus | 102.1 | 105.3 | 101.1 | 103.1 | is impossible |
| | Sub | Type | Nonwoven | Nonwoven | Nonwoven | Nonwoven | |
| | pad | | fabric | fabric | fabric | fabric | |
| | | Thickness (mm) | 1.1 | 1.1 | 1.1 | 1.1 | |
| | | Hardness (C.) | 70 | 70 | 70 | 70 | |
| | Stack | Thickness (mm) | 3.32 | 3.32 | 3.32 | 3.32 | |
| | pad | Compressibility (%) | 1.05 | 1.05 | 1.05 | 1.05 | |

### Experimental Example 2

Measuring Pore Sizes of Polishing Layers

The diameter sizes of pores for the polishing layers of Examples and Comparative Examples above were measured. Specifically, cross sections were observed from images obtained by magnifying 1 mm² polishing surfaces that had been cut into a 1 m×1 mm square (thickness: 2 mm) by 100 times using a scanning electron microscope (SEM). The number average diameter of pores, the distribution diagram of the sum of the cross-sectional areas for each pore diameter, the number of pores, and the total area of the pores were obtained by measuring the diameters of all pores from the images obtained using an image analysis software. The width/length of the SEM 100×image=959.1 μm/1,279 μm.

The measurement results are as shown in Table 3 and FIGS. 7 to 10 below.

TABLE 3

| | | | | | Comparative | Comparative | Comparative |
|---|---|---|---|---|---|---|---|
| Item | | Unit | Example 1 | Example 2 | Example 1 | Example 2 | Example 3 |
| Pore | D10 | μm | 13.4 | 14.9 | 26.4 | 21.5 | Casting is |
| Size | D50 | | 18.9 | 21.6 | 40.9 | 31.1 | impossible |
| | D90 | | 23.5 | 27.2 | 63.1 | 46.5 | |

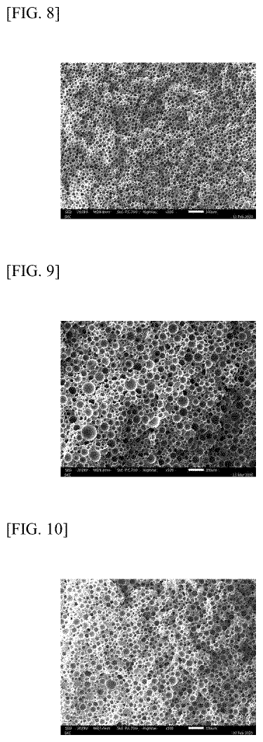

Table 3 above shows results of measuring the sizes of pores. It can be confirmed from the SEM measurement photos of FIGS. 7 and 8 and Examples that the polishing layers have a narrow pore diameter distribution as well as a very small average pore diameter.

On the other hand, it can be confirmed according to Table 3 above and FIGS. 9 and 10 that the size distributions of the pores are not uniform in Comparative Examples.

### Experimental Example 3

Measurement of Sₚₖ Reduction Rates

After installing a silicon wafer with a diameter of 300 mm on which silicon oxide had been deposited by a CVD process using CMP polishing equipment, the silicon wafer was set on a surface plate to which the polishing pads of Examples and Comparative Examples were attached so that the silicon oxide layer of the silicon wafer faced down.

Thereafter, the polishing load was adjusted to become 4.0 psi, and the silicon oxide film was polished by rotating the surface plate at 150 rpm for 60 seconds while injecting the calcined ceria slurry onto the polishing pads at a rate of 250 ml/min while rotating the polishing pads at 150 rpm. After polishing, the silicon wafer was removed from the carrier, mounted on a spin dryer, washed with purified water (DIW), and then dried with nitrogen for 15 seconds.

Changes in Sₚₖ values before and after polishing were measured under the conditions of Table 4 below using a roughness measuring device (manufacturer: Bruker, model name: contour-gt) before/after polishing.

TABLE 4

| | | Measurement | |
|---|---|---|---|
| | Detail | conditions | |
| Measurement | Measurement mode | VSI/VXI | |
| | Eye lens | 5 | magnification |
| | Objective lens | 1.5 | magnification |
| Measuring area | X-axis | 1182.6 | μm |
| | Y-axis | 893.8 | μm |
| Scan options | Speed | x1 | |
| | Backscan | 10 | μm |
| | Length | 80 | μm |

| | |
|---|---|
| Threshold value | 5% |

The measured Sₚₖ values were calculated according to Equation 1 below and were calculated as the Sₚₖ reduction rates.

$$\frac{\vert Initial {S}_{pk} - After polishing {S}_{pk} \vert}{Initial {S}_{pk}} \qquad [ Equation 1 ]$$

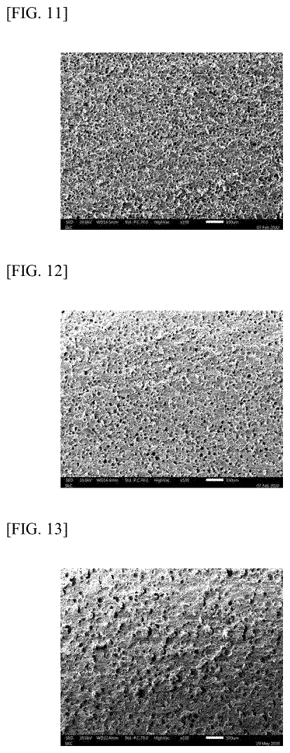

The Sₚₖ reduction rate measurement results of the polishing surfaces according to the above experiment are as shown in FIGS. 11 to 18 and Table 5 below.

TABLE 5

| | Initial | After CMP | |
|---|---|---|---|
| Pad | Sₚₖ | Sₚₖ | Sₚₖ reduction rate |
| Example 1 | 4.4 | 4.1 | 6.82% |
| Example 2 | 4.7 | 5.2 | 10.64% |
| Comparative Example 1 | 7.6 | 5.0 | 34.21% |
| Comparative Example 2 | 7.4 | 5.3 | 28.38% |

| | |
|---|---|
| Comparative Example 3 | Manufacturing of pads is impossible |
| | due to impossible casting |

According to Table 5 above, for the polishing surfaces of the polishing layers according to Examples of the present disclosure, the initial Sₚₖ values and the measured Sₚₖ values after the process as the Sₚₖ measurement values are the same as in Table 5 above, and it can be confirmed that the Sₚₖ measurement values have insignificant effects on the surface roughness as the results of the SEM photographs of the polishing surfaces after the polishing process are also confirmed in FIGS. 15 and 16 of ×300 magnification as well as in FIGS. 11 and 12 of ×100 magnification. Accordingly, the Sₚₖ reduction rates were shown to be also within the scope of the present disclosure.

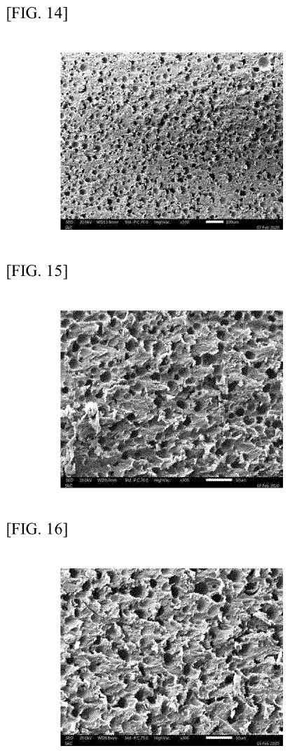

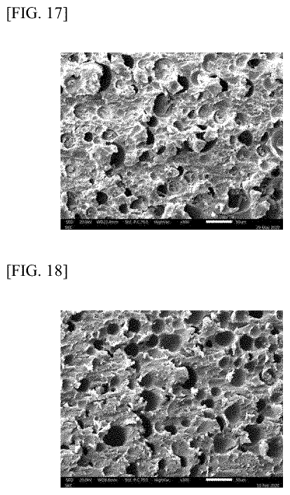

Meanwhile, in the case of Comparative Examples, it can be confirmed that the surface roughness values are reduced in FIGS. 17 and 18 of ×300 magnification as well as in FIGS. 13 and 14 of ×100 magnification, and it was confirmed that large reduction rates were shown in the calculation results of the Sₚₖ reduction rates.

### Experimental Example 4

Measurement of Polishing Performance

Method of Measuring the Polishing Rate (Removal Rate)

After installing a silicon wafer with a diameter of 300 mm on which silicon oxide had been deposited by a CVD process using CMP polishing equipment, the silicon wafer was set on a surface plate to which the polishing pads of Examples and Comparative Examples were attached so that the silicon oxide layer of the silicon wafer faced down. Thereafter, the polishing load was adjusted to become 4.0 psi, and the silicon oxide film was polished by rotating the surface plate at 150 rpm for 60 seconds while injecting the calcined ceria slurry onto the polishing pads at a rate of 250 ml/min while rotating the polishing pads at 150 rpm. After polishing, the silicon wafer was removed from the carrier, mounted on a spin dryer, washed with purified water (DIW), and then dried with nitrogen for 15 seconds. Changes in the film thickness of the dried silicon wafer before and after polishing were measured using an optical interference type thickness measuring device (manufacturer: Kyence, model name: SI-F8OR). Thereafter, the polishing rate was calculated using Equation 1 below.

Polishing rate=Silicon wafer polishing thickness (Å)/polishing time (60 seconds) [Equation 1]

Polishing Pad Cut-Rate (μm/hr)

The polishing pads of Examples and Comparative Examples were pre-conditioned with deionized water for initial 10 minutes, and then conditioned while being sprayed with deionized water for 1 hour. At this time, the thickness changes thereof during conditioning for 1 hour were measured. Equipment used for conditioning was CTS' AP-300HM, the conditioning pressure was 6 lbf, the rotational speed was 100 to 110 rpm, and the disk used for conditioning was Saesol CI-45.

Method of Measuring Defects

Polishing was performed in the same manner as the polishing rate measuring method by using CMP polishing equipment. After polishing, the silicon wafers were moved to a cleaner and cleaned for 10 seconds each using 1% HF and purified water (DIW), and 1% H₂NO₃ and purified water (DIW). Thereafter, they were moved to a spin dryer, washed with purified water (DIW), and then dried with nitrogen for 15 seconds. Defect changes of the dried silicon wafers before and after polishing were measured using defect measuring equipment (manufacturer: Tenkor, model name: XP+).

The experimental results are as shown in Table 6 below.

TABLE 6

| | | | | Comparative | Comparative | Comparative |
|---|---|---|---|---|---|---|
| SMPL | | Example 1 | Example 2 | Example 1 | Example 2 | Example 3 |
| Ceria | Ox RR | 2799 | 2831 | 2811 | 2838 | Manufacturing |
| slurry | (Å/min) | | | | | of pads is |
| | Cut-rate | 19.4 | 19.2 | 19.1 | 19.1 | impossible due |
| | (μm/hr) | | | | | to impossible |

| | | | | | |
|---|---|---|---|---|---|
| Sₚₖ reduction rate | 6.82% | 10.64% | 34.21% | 28.38% | casting |
| Defects/Scratches | 0 | 2 | 121 | 101 | |

According to Table 6 above, it was shown in the polishing pads according to Examples of the present disclosure that the Sₚₖ reduction rates corresponded to within the range of the present disclosure, and defects were not present or were present in an insignificant level after the polishing process. Meanwhile, it was confirmed in the case of Comparative Examples that the Sₚₖ reduction rates were shown to be large, and very many defects occurred after the polishing process accordingly.

Hereinabove, preferred embodiments of the present disclosure have been described in detail, but the right scope of the present disclosure is not limited thereto, and various modified and improved forms of those skilled in the art using the basic concept of the present disclosure defined in the following claims also belong to the right scope of the present disclosure.

### EXPLANATION OF MARKS

10: Unexpanded particles

11: Shell of the unexpanded particles

12: Expansion-causing component

20: Expanded particles

30: Curing process

40: Pores in a polishing layer

110: Polishing pad

120: Surface plate

130: Semiconductor substrate

140: Nozzle

150: Polishing slurry

160: Polishing head

170: Conditioner

What is claimed is:

1. A polishing pad comprising a polishing layer, wherein a polishing surface of the polishing layer has a Sₚₖ reduction rate according to the following Equation 1 of 5 to 25%:
$$\frac{\vert Initial {S}_{pk} - After polishing {S}_{pk} \vert}{Initial {S}_{pk}} \qquad [ Equation 1 ]$$
where,
Sₚₖ relates to a three-dimensional parameter for surface roughness, and means the average height of the protruding peak after expressing the height of the total surface roughness in a graph,
the initial Sₚₖ is Sₚₖ for the polishing surface before the polishing process, and
Sₚₖ after polishing is Sₚₖ for the polishing surface after attaching a 300 mm diameter silicon wafer on which silicon oxide is deposited to a surface plate, maintaining a polishing load of 4.0 psi and a rotational speed of the polishing pad of 150 rpm, injecting the calcined ceria slurry at a rate of 250 ml/min, and performing the polishing process for 60 seconds.

2. The polishing pad of claim 1, wherein the polishing layer includes a plurality of pores, and the pores have a D10 of 10 to 20 μm.

3. The polishing pad of claim 2, wherein the pores have a D50 of 15 to 30 μm.

4. The polishing pad of claim 2, wherein the pores have a D90 of 20 to 45 μm.

5. The polishing pad of claim 1, wherein the polishing layer contains a cured product of a composition for manufacturing a polishing layer, comprising a prepolymer composition, a foaming agent, a curing agent, and a catalyst.

6. The polishing pad of claim 5, wherein the foaming agent is an unexpanded solid-phase foaming agent.

7. The polishing pad of claim 6, wherein the unexpanded solid-phase foaming agent comprises a resin material shell and an expansion-causing component that is encapsulated inside the shell.

8. The polishing pad of claim 7, wherein the shell contains a thermoplastic resin.

9. The polishing pad of claim 7, wherein the expansion-causing component is selected from the group consisting of a hydrocarbon compound, a chlorofluoro compound, a tetraalkylsilane compound, and combinations thereof.

10. The polishing pad of claim 5, wherein the foaming agent is contained in an amount of 0.5 to 10 parts by weight with respect to 100 parts by weight of the prepolymer composition.

11. The polishing pad of claim 5, wherein the catalyst is selected from the group consisting of an amine-based catalyst, a bismuth-based metal catalyst, an Sn-based metal catalyst, and mixtures thereof.

12. The polishing pad of claim 11, wherein the catalyst is contained in an amount of 0.001 to 0.01 parts by weight with respect to 100 parts by weight of the prepolymer composition.

13. A method for manufacturing a polishing pad, the method comprising the steps of:
i) preparing a prepolymer composition;
ii) preparing a composition for manufacturing a polishing layer, comprising the prepolymer composition, a foaming agent, a curing agent, and a catalyst; and
iii) manufacturing a polishing layer by curing the composition for manufacturing the polishing layer,
wherein a polishing surface of the polishing layer has a Sₚₖ reduction rate according to the following Equation 1 of 5 to 25%:
$$\frac{\vert Initial {S}_{pk} - After polishing {S}_{pk} \vert}{Initial {S}_{pk}} \qquad [ Equation 1 ]$$
where,
Sₚₖ relates to a three-dimensional parameter for surface roughness, and means the average height of the protruding peak after expressing the height of the total surface roughness in a graph,
the initial Sₚₖ is Sₚₖ for the polishing surface before the polishing process, and
Sₚₖ after polishing is Sₚₖ for the polishing surface after attaching a 300 mm diameter silicon wafer on which silicon oxide is deposited to a surface plate, maintaining a polishing load of 4.0 psi and a rotational speed of the polishing pad of 150 rpm, injecting the calcined ceria slurry at a rate of 250 ml/min, and performing the polishing process for 60 seconds.

14. The method of claim 13, wherein the foaming agent is an unexpanded solid-phase foaming agent.

15. The method of claim 14, wherein the unexpanded solid-phase foaming agent is expanded by the curing process of the step iii) to form a plurality of pores with a uniform size.

16. The method of claim 13, wherein the foaming agent is contained in an amount of 0.5 to 10 parts by weight with respect to 100 parts by weight of the prepolymer composition.

17. The method of claim 13, wherein the composition for manufacturing the polishing layer is injected into a preheated mold and cured.

18. The method of claim 13, wherein the catalyst is selected from the group consisting of an amine-based catalyst, a bismuth-based metal catalyst, an Sn-based metal catalyst, and mixtures thereof.

19. The method of claim 18, wherein the catalyst is contained in an amount of 0.001 to 0.01 parts by weight with respect to 100 parts by weight of the prepolymer composition.

20. A method for manufacturing a semiconductor device, the method comprising the steps of:
1) providing a polishing pad comprising a polishing layer; and
2) polishing the semiconductor substrate while relatively rotating them so that the surface to be polished of a semiconductor substrate comes into contact with a polishing surface of the polishing layer,
wherein the polishing surface of the polishing layer has a Sₚₖ reduction rate according to the following Equation 1 of 5 to 25%:
$$\frac{\vert Initial {S}_{pk} - After polishing {S}_{pk} \vert}{Initial {S}_{pk}} \qquad [ Equation 1 ]$$
where,
Sₚₖ relates to a three-dimensional parameter for surface roughness, and means the average height of the protruding peak after expressing the height of the total surface roughness in a graph,
the initial Sₚₖ is Sₚₖ for the polishing surface before the polishing process, and
Sₚₖ after polishing is Sₚₖ for the polishing surface after attaching a 300 mm diameter silicon wafer on which silicon oxide is deposited to a surface plate, maintaining a polishing load of 4.0 psi and a rotational speed of the polishing pad of 150 rpm, injecting the calcined ceria slurry at a rate of 250 ml/min, and performing the polishing process for 60 seconds.
